(19) United States
(12) Patent Application Publication
(10) Pub. No.: US 2025/0207987 A1
(43) Pub. Date: Jun. 26, 2025

(54) PRESSURE/STRAIN SENSOR DESIGN IN A COMPLEMENTARY METAL OXIDE SEMICONDUCTOR (CMOS) PROCESS

(71) Applicant: QUALCOMM Incorporated, San Diego, CA (US)

(72) Inventors: Abhijeet PAUL, San Diego, CA (US); Mishel MATLOUBIAN, San Diego, CA (US); Hsian CHEN, Hsinchu (TW)

(21) Appl. No.: 18/391,389

(22) Filed: Dec. 20, 2023

(51) Int. Cl. G01L 1/22; H01L 21/8249; H01L 27/06

(52) U.S. Cl. CPC G01L 1/2293; H10D 84/0109; H10D 84/038; H10D 84/204; H10D 84/611

(57) ABSTRACT

An integrated circuit (IC) structure is described, including a substrate and a device on the substrate. The IC structure also includes a first contact field plate above the device. The IC structure further includes a dielectric layer between the first contact field plate and the device. The IC structure also includes a pressure/strain terminal coupled to the first contact field plate.

### BACKGROUND

### Field

Aspects of the present disclosure relate to semiconductor devices and, more particularly, to a method and apparatus for a pressure/strain sensor design in a complementary metal oxide semiconductor (CMOS) process.

### Background

As integrated circuit (IC) technology advances, device geometries are reduced. Technological advances in IC materials and designs have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down also increases the complexity of processing and manufacturing ICs. Moreover, realizing these advancements involves similar developments in IC processing and manufacturing of advanced logic complementary metal oxide semiconductor (CMOS) transistors.

Advanced logic CMOS scaling achieves a performance-power-area (PPA) boost over past process nodes. Unfortunately, circuit elements in advanced process nodes may be subjected to external pressure/strain. A mechanism for sensing external pressure/strain is desired to efficiently transfer the pressure/strain from outside to a sensing element without affecting other circuit elements, creating electrostatic discharge (ESD) paths, and/or involving expensive packaging. Conventional mechanisms for sensing external pressure/strain are either expensive, not well integrated with a semiconductor process (e.g., a CMOS process), or have poor sensitivity. Therefore, a method and apparatus for a pressure/strain sensor design in a semiconductor process is desired.

### SUMMARY

An integrated circuit (IC) structure is described, including a substrate and a device on the substrate. The IC structure also includes a first contact field plate above the device. The IC structure further includes a dielectric layer between the first contact field plate and the device. The IC structure also includes a pressure/strain terminal coupled to the first contact field plate.

A method for fabricating a pressure/strain sensing device using an integrated circuit (IC) structure is described. The method includes forming an active/passive device on a substrate. The method also includes forming a first contact field plate above the active/passive device. The method further includes depositing a dielectric layer between the first contact field plate and the active/passive device. The method also includes forming a pressure/strain terminal coupled to the first contact field plate.

This has outlined, broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for conducting the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer, which may be used for fabricating a pressure/strain sensing device, according to various aspects of the present disclosure.

FIG. 2 illustrates a cross-sectional view of the die of FIG. 1, which may be used for fabricating a pressure/strain sensing device, according to various aspects of the present disclosure.

FIG. 3 illustrates a cross-sectional view of a metal oxide semiconductor field effect transistor (MOSFET) device.

FIGS. 4A and 4B are block diagrams illustrating a complementary metal oxide semiconductor (CMOS) integrated circuit (IC) pressure/strain sensing device, according to various aspects of the present disclosure.

FIGS. 5A-5C are block diagrams illustrating integration of the complementary metal oxide semiconductor (CMOS) integrated circuit (IC) pressure/strain sensing device of FIG. 4A on a die, according to various aspects of the present disclosure.

FIGS. 6A-6H are block diagrams illustrating a pressure/strain sensing device utilizing an integrated circuit (IC) structure, according to various aspects of the present disclosure.

FIGS. 7A-7E are block diagrams illustrating design variations of a strain/pressure sensitive resistor, according to various aspects of the present disclosure.

FIGS. 8A-8C are block diagrams illustrating alternative contact field plate (CFP) implementations of a pressure/strain sensing device, according to various aspects of the present disclosure.

FIG. 9 is a process flow diagram illustrating a method for fabricating a pressure/strain sensing device using an integrated circuit (IC) structure, according to various aspects of the present disclosure.

FIG. 10 is a block diagram showing an exemplary wireless communications system, in which an aspect of the present disclosure may be advantageously employed.

FIG. 11 is a block diagram illustrating a design workstation used for circuit, layout, and logic design of an integrated circuit (IC) structure, in accordance with various aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

As integrated circuit (IC) technology advances, device geometries reduce. Technological advances in IC materials and designs have produced generations of ICs in which each generation has smaller and more complex circuits than the previous generation. In the course of IC evolution, functional density has increased while geometry size has decreased. This scaling down process provides benefits by increasing production efficiency and lowering associated costs. Such scaling down also increases the complexity of processing and manufacturing ICs. Moreover, realizing these advancements involves similar developments in IC processing and manufacturing of advanced logic complementary metal oxide semiconductor (CMOS) transistors.

Advanced logic CMOS scaling achieves a performance-power-area (PPA) boost over past process nodes. Unfortunately, circuit elements in advanced process nodes may be subjected to external pressure/strain. A mechanism for sensing external pressure/strain is desired to efficiently transfer the pressure/strain from outside to a sensing element without affecting other circuit elements, creating electrostatic discharge (ESD) paths, and/or involving expensive packaging. Conventional mechanisms for sensing external pressure/strain are either expensive, not well integrated with a semiconductor process (e.g., a CMOS process), or have poor sensitivity. Therefore, a method and apparatus for a pressure/strain sensor design in a semiconductor process is desired.

Various aspects of the present disclosure are directed to methods and apparatuses for a pressure/strain sensor design in a CMOS process. The process flow for fabricating a pressure/strain sensing device may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably unless such interchanging would tax credulity.

A pressure/strain sensing device utilizes an integrated circuit (IC) structure, including a substrate having an active and/or passive device in the substrate. Additionally, the IC structure includes a contact field plate above the active/passive device. The IC structure further includes a dielectric layer between the contact field plate and the active/passive device to provide a direct pressure/strain contact between the active/passive device and the contact field plate. In various aspects of the present disclosure, a first (M1) metal layer is coupled to the contact field plate to provide a pressure/strain terminal of a pressure/strain sensing device.

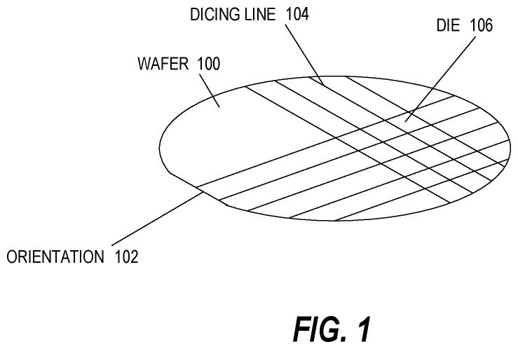

FIG. 1 illustrates a perspective view of a semiconductor wafer, which may be used for fabricating a pressure/strain sensing device, according to various aspects of the present disclosure. A wafer 100 may be a semiconductor wafer or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a single material (e.g., silicon (Si), germanium (Ge)) or a compound material, such as gallium arsenide (GaAs), gallium nitride (GaN), or indium phosphide (InP), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100. Additionally, a wafer direction may also be [111], which is used for GaN, or other like compound materials.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, diverse types of electronic devices may be formed in or on the wafer 100.

The wafer 100 has an orientation 102 that indicates the crystalline orientation of the wafer 100. The orientation 102 may be a flat edge of the wafer 100 as shown in FIG. 1 or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and C, which are the Miller indices for a plane (hkl) in the crystal. Each index denotes a plane orthogonal to a direction (h, k, l) on the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to C. For some crystals, negative numbers are used (written as a bar over the index number) and for some crystals, such as gallium nitride, more than three numbers may be employed to describe the different crystallographic planes. For example, a wafer direction of for the waver 100 is possible, which is used for GaN, or other like compound materials, although other wafer directions are contemplated according to various aspects of the present disclosure.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

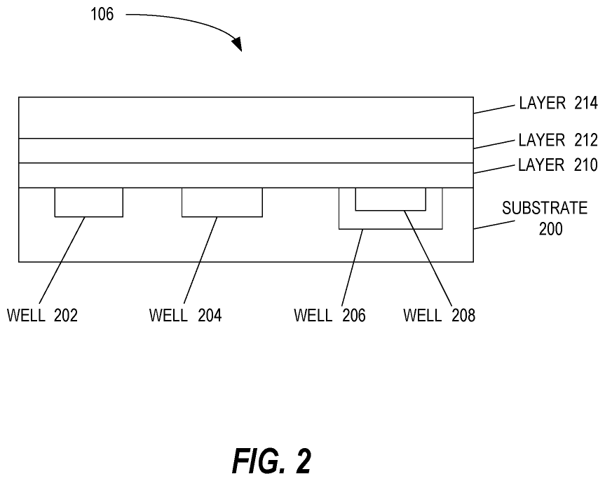

FIG. 2 illustrates a cross-sectional view of the die 106 of FIG. 1, which may be used for fabricating a pressure/strain sensing device, according to various aspects of the present disclosure. In the die 106, there may be a substrate 200, which may be a semiconductor material and/or may function as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within the substrate 200 (e.g., a semiconductor substrate), there may be wells 202 and 204 of a field effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT), which may be used for formation of the pressure/strain sensing device. The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may be composed of a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure.

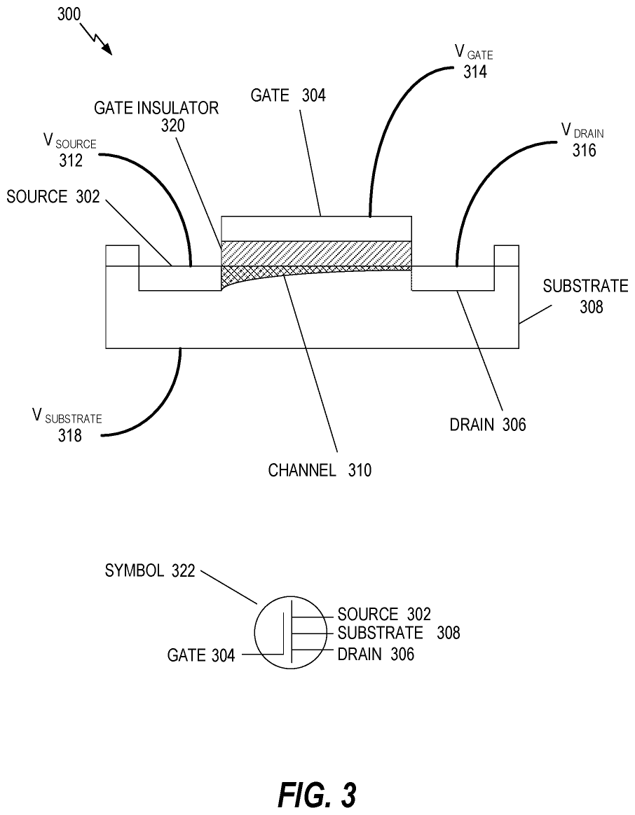

FIG. 3 illustrates a cross-sectional view of a metal oxide semiconductor field effect transistor (MOSFET) device 300. The MOSFET device 300 may have four input terminals. The four inputs are a source 302, a gate 304, a drain 306, and a body. The source 302 and the drain 306 may be fabricated as the wells 202 and 204 in a substrate 308 or may be fabricated as areas above the substrate 308, or as part of other layers on the die 106 of FIG. 1. Such other structures may be a fin or other structure that protrudes from a surface of the substrate 308. Further, the substrate 308 may be the substrate 200 on the die 106, but the substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314, or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For P-type MOSFETs (using holes as charge carriers in the channel 310), an arrow is applied to the substrate 308 terminal in the symbol 322 pointing toward the gate 304 terminal.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304, as described below.

To interconnect to the MOSFET device 300, or to interconnect to other devices in the die 106 (e.g., semiconductor), interconnect traces or layers are used. These interconnect traces may be in one or more layers (e.g., 210-214), or may be in other layers of the die 106.

Advanced logic CMOS scaling achieves a performance-power-area (PPA) boost over past process nodes. Unfortunately, circuit elements in advanced process nodes may be subjected to external pressure/strain. A mechanism for sensing external pressure/strain is desired to efficiently transfer the pressure/strain from outside to a sensing element without affecting other circuit elements, creating electrostatic discharge (ESD) paths, and/or involving expensive packaging. Unfortunately, conventional mechanisms for sensing external pressure/strain are either expensive, not well integrated with a semiconductor process (e.g., CMOS process), or have poor sensitivity. Therefore, a method and apparatus for a pressure/strain sensor design in a semiconductor process is desired.

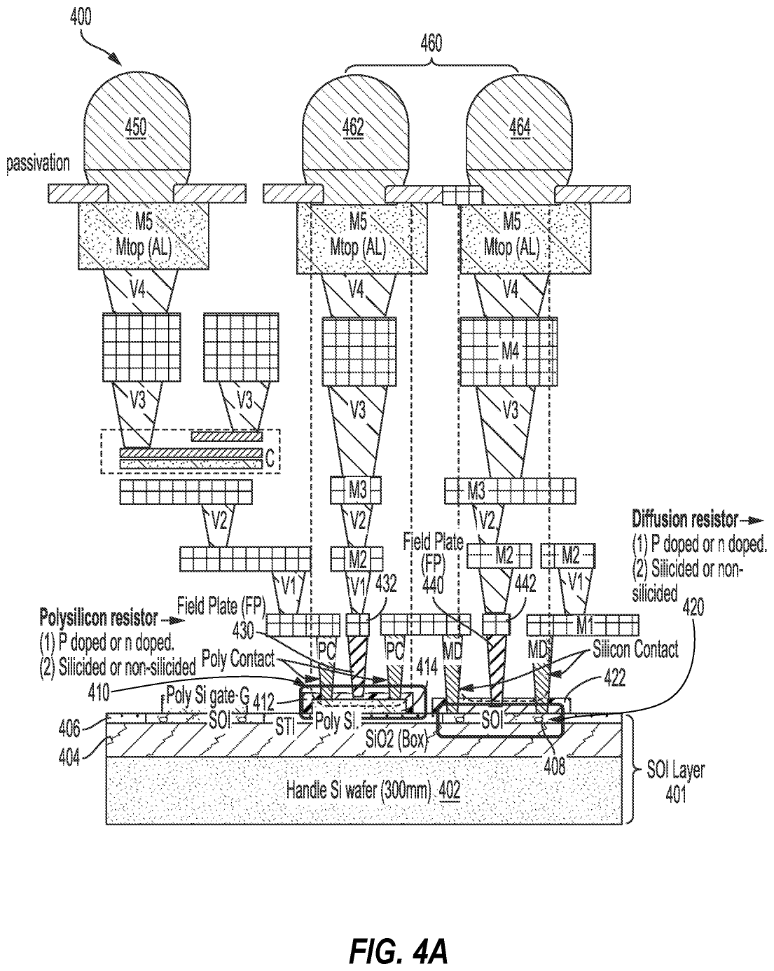

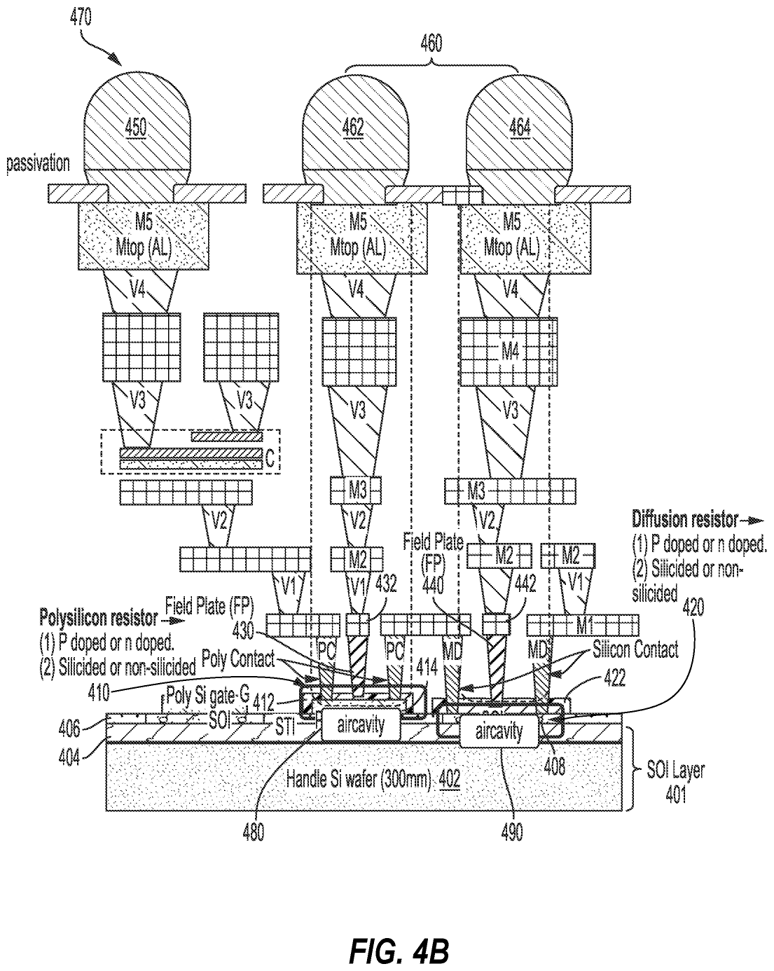

In response, various aspects of the present disclosure are directed to methods for creating an efficient mechanical path from an external sensing plate to a sensor element for non-electrical strain transfer. In various aspects of the present disclosure, a pressure/strain sensor element may include, but is not limited to: (1) a piezo resistance of poly silicon or silicon (diffusion) resistors, (2) a bipolar junction transistor, (3) a diode, or (4) a MOSFET or any other IC element sensitive to strain. In some aspects of the present disclosure, the external strain is transferred using a stack of vias that originate from an external bump/plate and terminate with a contact field plate (commonly used for surface electric field control in power FETs), the closest non-electrical contact to the sensing elements listed above. This aspect of the present disclosure provides a method for external strain transfer to an internal device on an IC structure, for example, as shown in FIGS. 4A and 4B.

FIGS. 4A and 4B are block diagrams illustrating a complementary metal oxide semiconductor (CMOS) integrated circuit (IC) pressure/strain sensing device, according to various aspects of the present disclosure. As shown in FIG. 4A, an IC pressure/strain sensing device 400 includes a semiconductor-on-insulator (SOI) substrate 401 having a buried oxide (BOX) layer 404 on a handle wafer 402. Additionally, the SOI substrate 401 includes an SOI layer 408, separated by shallow trench isolation (STI) layers 406, on the BOX layer 404. Although shown as the SOI substrate 401, it should be recognized that the IC pressure/strain sensing device 400 may be implemented using a bulk substrate, such as a bulk silicon (Si) substrate.

As shown in FIG. 4A, the IC pressure/strain sensing device 400 includes a polysilicon gate (G) on the SOI layer 408. Additionally, the IC pressure/strain sensing device 400 includes a first resistor 410 on the STI layer 406, and a second resistor 420 on the SOI layer 408. In this example, the first resistor 410 is a polysilicon resistor, having a polysilicon layer 414, which may be P-type doped or N-type doped. Additionally, the second resistor 420 is a complementary metal oxide semiconductor (CMOS) diffusion resistor, including the SOI layer 408, which may be P-type doped or N-type doped.

In various aspects of the present disclosure, the IC pressure/strain sensing device 400 includes a first contact field plate 430 above (e.g., over) the polysilicon layer 414. The IC pressure/strain sensing device 400 further includes a dielectric layer 412 (e.g., fluorosilicate glass (FSG) oxide, silicon nitride (SiN), or titanium nitride (TiN)) between the first contact field plate 430 and the polysilicon layer 414 to provide a mechanical pressure contact directly between the polysilicon layer 414 and the first contact field plate 430. Additionally, a first (M1) metal layer is coupled to the first contact field plate 430 for providing a first pressure/strain terminal 432 of the IC pressure/strain sensing device 400. The M1 metal layer is also contacted to the polysilicon layer 414 through poly contacts (PC), using a silicided contact or a non-silicided contact. In various aspects of the present disclosure, a thickness of the dielectric layer 412 under the contact field plate 430 and/or the dielectric layer 422 under the contact field plate 440 is variable before placement of the contact field plate 430 or the contact field plate 440. This variable thickness configuration of the dielectric layer 412 and/or the dielectric layer 422, which provides a differential pressure signal for improved analog detection and noise cancellation.

Additionally, the IC pressure/strain sensing device 400 includes a second contact field plate 440 on the SOI layer 408. The IC pressure/strain sensing device 400 further includes a dielectric layer 422 (e.g., fluorosilicate glass (FSG) oxide, silicon nitride (SiN), or titanium nitride (TiN)) between the second contact field plate 440 and the SOI layer 408 to provide a mechanical pressure contact directly between the SOI layer 408 and the second contact field plate 440. Additionally, a first (M1) metal layer is coupled to the second contact field plate 440 and provides a second pressure/strain terminal 442 of the IC pressure/strain sensing device 400. The M1 metal layer is also contacted to the SOI layer 408 through metal to diffusion (MD) contacts, using a silicided contact or a non-silicided contact.

As further illustrated in FIG. 4A, a first (V1) via, a second (M2) metal layer, a second (V2) via, a third (M3) metal layer, a third (V3) via, a fourth (M4) metal layer, a fourth (V4) via, and a fifth (M5) metal layer provide an external path from the first resistor 410 through the first pressure/strain terminal 432. In this example, the V1 via, the M2 metal layer, the V2 via, the M3 metal layer, the V3 via, the M4 metal layer, the V4 via, and the M5 metal layer provide an external path from the first pressure/strain terminal 432 to a first external pressure/strain sense bump 462 of a pair of external pressure/strain sense bumps 460. Additionally, the V1 via, the M2 metal layer, the V2 via, the M3 metal layer, the V3 via, the M4 metal layer, the V4 via, and the M5 metal layer provide an external path from the second resistor 420 through the second pressure/strain terminal 442. In this example, the V1 via, the M2 metal layer, the V2 via, the M3 metal layer, the V3 via, the M4 metal layer, the V4 via, and the M5 metal layer provide an external path from the second pressure/strain terminal 442 to a second external pressure/strain sense bump 464 of the pair of external pressure/strain sense bumps 460.

As further illustrated in FIG. 4A, the V1 via, the M2 metal layer, the V2 via, the M3 metal layer, the V3 via, the M4 metal layer, the V4 via, and the M5 metal layer provide an external path from the first resistor 410 to an electrical bump 450. In this example, a capacitor (C) (e.g., a metal-insulator-metal (MIM) cap or a metal oxide metal (MOM) cap) is formed between the M3 metal layer and V3 vias. Although shown to include five metal layers, it should be recognized that different configurations of the IC pressure/strain sensing device 400 may have a different number of metal layers. The V1 via, the M2 metal layer, the V2 via, the M3 metal layer, the V3 via, the M4 metal layer, the V4 via, and the M5 metal layer may be composed of a conductive material such as copper, tungsten, aluminum, an alloy, or other conductive or metallic materials. In this example, the M5 metal layer is shown as composed of aluminum (Al).

FIG. 4B is a block diagram illustrating an IC pressure/strain sensing device 470, according to various aspects of the present disclosure. As shown in FIG. 4B, the IC pressure/strain sensing device 470 is described with similar reference numbers to the IC pressure/strain sensing device 400 shown in FIG. 4A. As shown in FIG. 4B, a sensitivity of the first resistor 410 and the second resistor 420 (and other active/passive sensing elements) can be increased by fabricating the first resistor 410 on a first air cavity 480 and fabricating the second resistor 420 on a second air cavity 490. According to various aspects of the present disclosure, fabricating a pressure/strain sensor (e.g., the first resistor 410 and/or the second resistor 420) on an air cavity (e.g., the first air cavity 480 and/or the second air cavity 490) supports more efficient response to external pressure and an increased sensitivity to the applied strain. According to various aspects of the present disclosure, a control device, similar to the sensing element, can also be added without an external connection to use as reference for more accurate strain measurements. For example, this configuration of the IC pressure/strain sensing device 470 may enable altitude detection, a shock sensor (e.g., to detect a fall/knocking off of a device), and/or a strain sensor (e.g., to detect a hit, such as a car hit of the device). In various aspects of the present disclosure, a thickness of the dielectric layer 412 under the contact field plate 430 and/or the dielectric layer 422 under the contact field plate 440 is variable, which provides a differential pressure signal for improved analog detection and noise cancellation to support the noted shock sensor and/or strain sensor configurations.

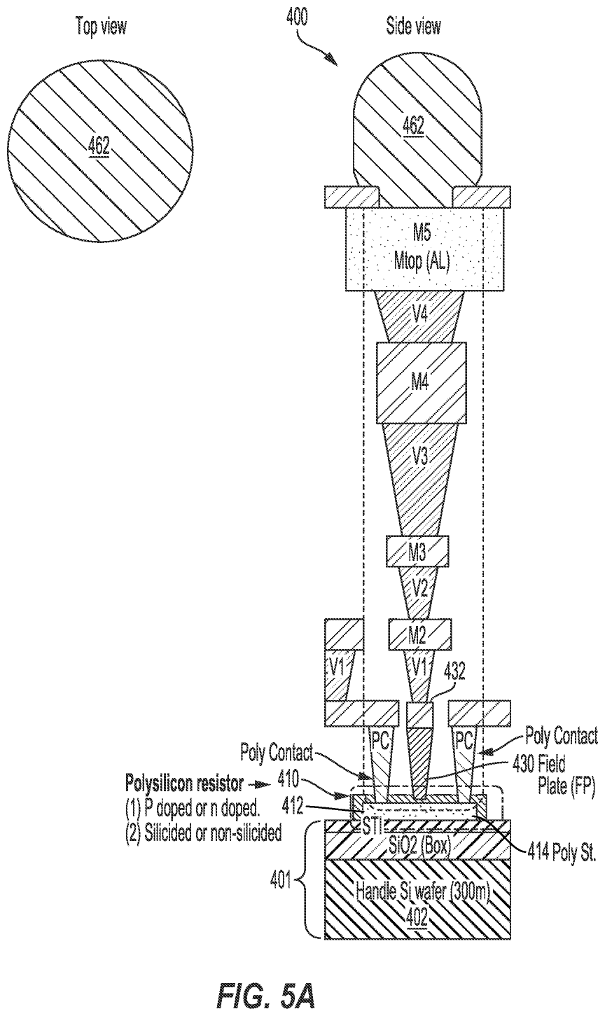

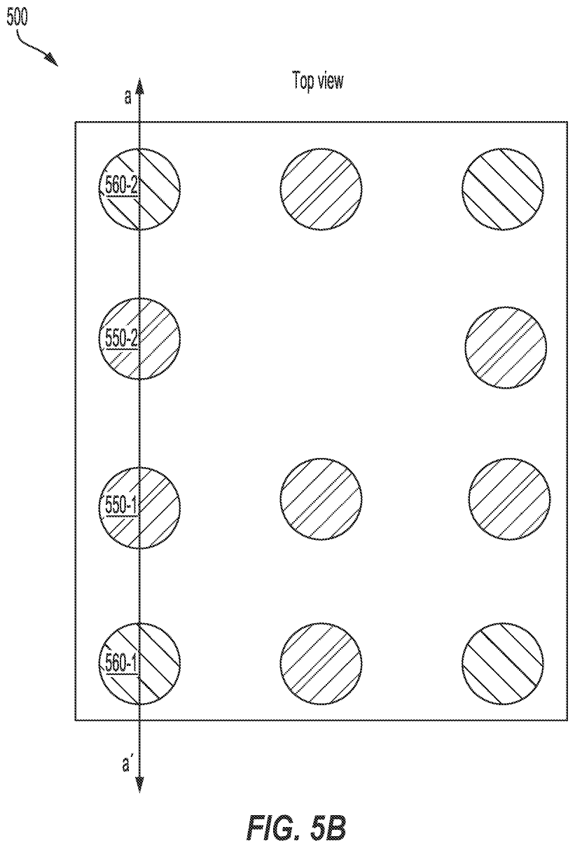

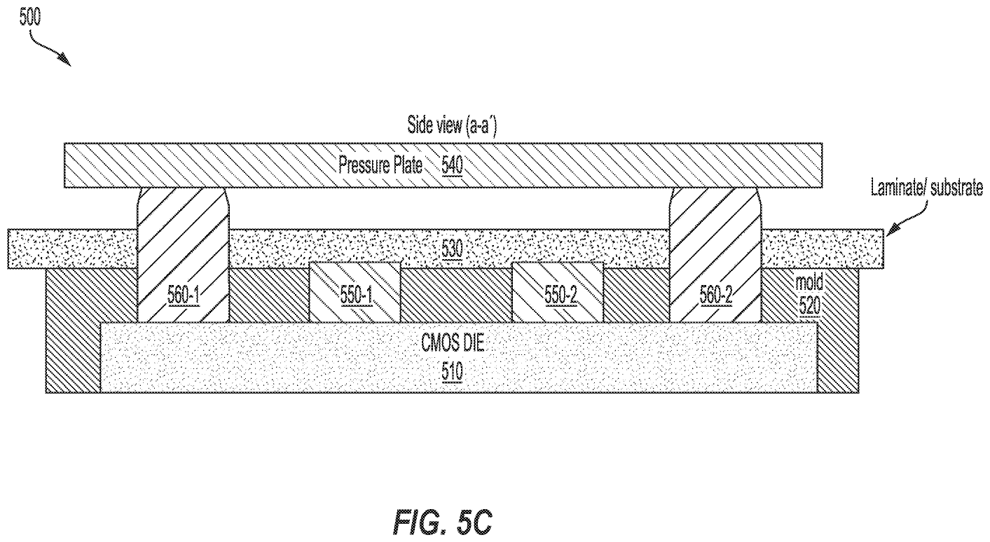

FIGS. 5A-5C are block diagrams illustrating integration of the complementary metal oxide semiconductor (CMOS) integrated circuit (IC) pressure/strain sensing device 400 of FIG. 4A on a die, according to various aspects of the present disclosure. FIG. 5A illustrates a top view and a side view of a portion of the IC pressure/strain sensing device 400 of FIG. 4A, according to various aspects of the present disclosure. In particular, a top view illustrates the first external pressure/strain sense bump 462. Additionally, the side view illustrates the portion of the IC pressure/strain sensing device 400 of FIG. 4A supporting the first external pressure/strain sense bump 462. In this example, the V1 via, the M2 metal layer, the V2 via, the M3 metal layer, the V3 via, the M4 metal layer, the V4 via, and the M5 metal layer provide an external path from the first external pressure/strain sense bump 462 to the first resistor 410 through the first pressure/strain terminal 432.

FIG. 5B illustrates a top view of integration of the portion of the IC pressure/strain sensing device 400 of FIG. 4A in a CMOS pressure sensor die 500, according to various aspects of the present disclosure. In the top view of FIG. 5B, a pair of external pressure/strain sense bumps 560 (560-1 and 560-2) are shown in combination with electrical bumps 550 (550-1 and 550-2). Additionally, a cutline aa′ is shown through the pair of external pressure/strain sense bumps 560 and electrical bumps 550 to further illustrate a cross-sectional view of the CMOS pressure sensor die 500 in FIG. 5C.

FIG. 5C illustrates a side view of the CMOS pressure sensor die 500 along the cutline aa′ of FIG. 5B, according to various aspects of the present disclosure. In this example, the CMOS pressure sensor die 500 includes the electrical bumps 550 and the pair of external pressure/strain sense bumps 560 coupled to a surface of a CMOS die 510. The electrical bumps 550 extend through a mold 520 and are coupled between a laminate/substrate 530 and the CMOS die 510. Additionally, the pair of external pressure/strain sense bumps 560 extend through the mold 520 and the laminate/substrate 530 to support an external pressure plate 540. Although FIGS. 5A-5C illustrate one example integration of the electrical bumps 550 and the pair of external pressure/strain sense bumps 560, other integrations of the electrical bumps 550 and the pair of external pressure/strain sense bumps 560 are completed, for example, to integrate the external pressure/strain sense bumps 560 with a die package.

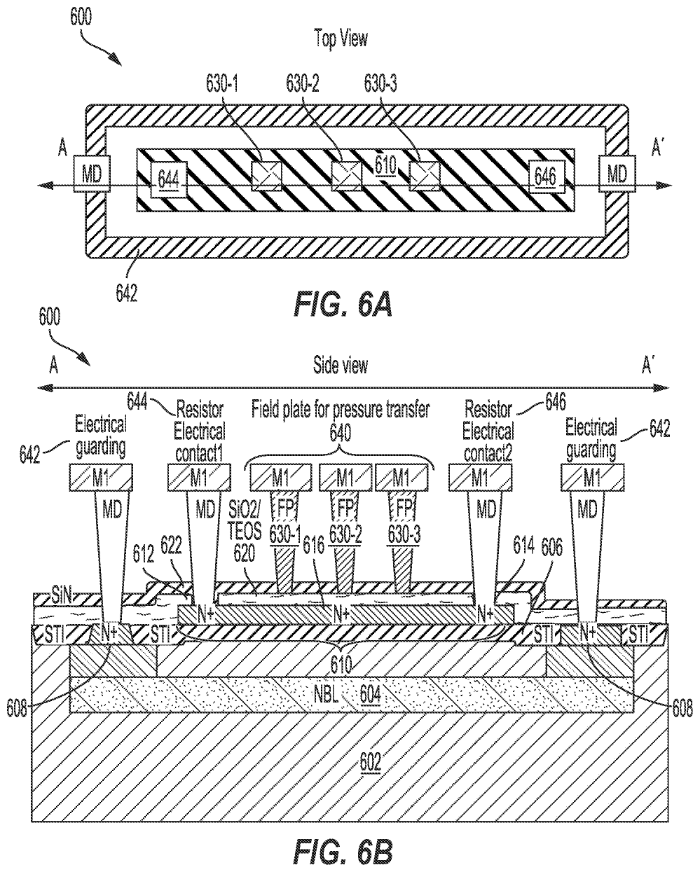

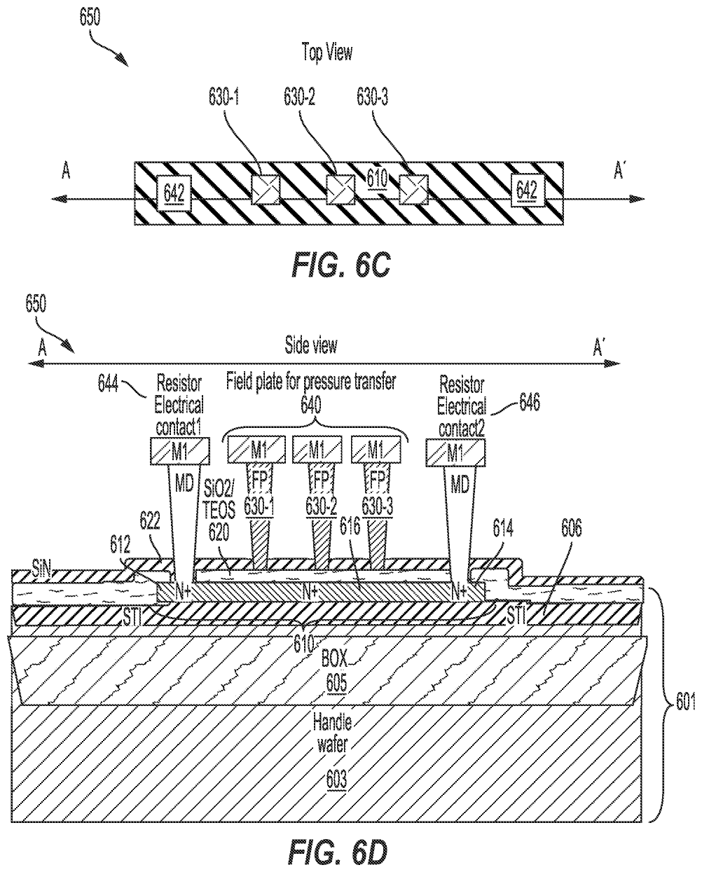

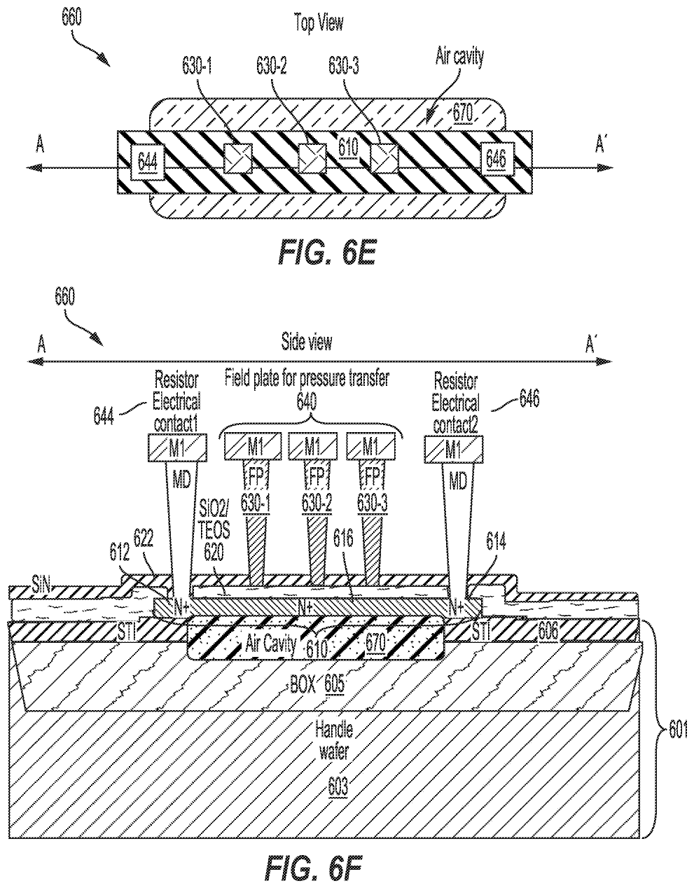

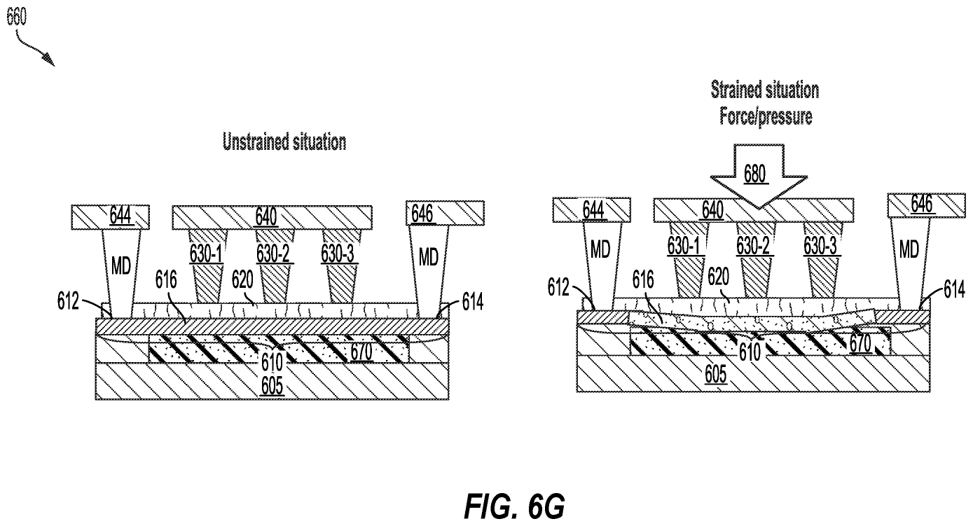

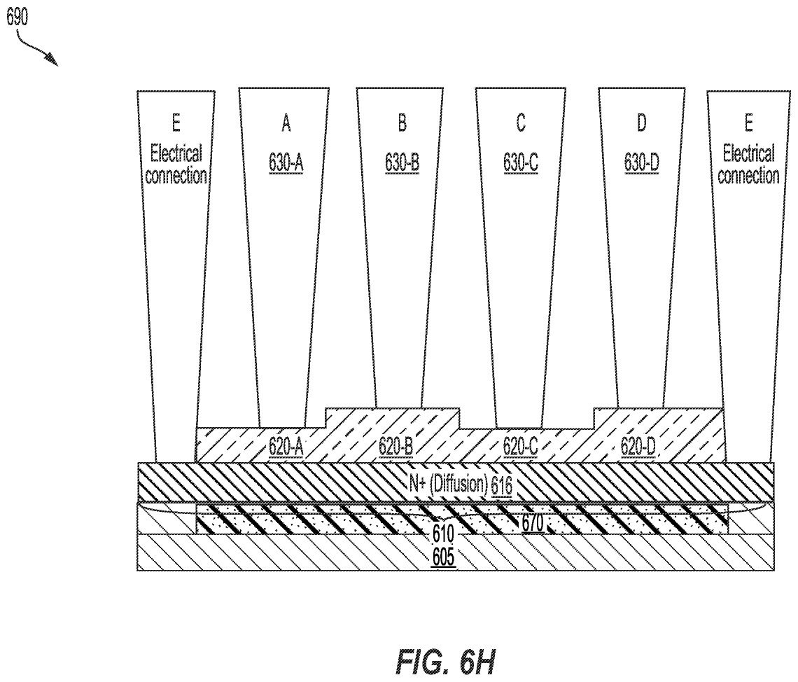

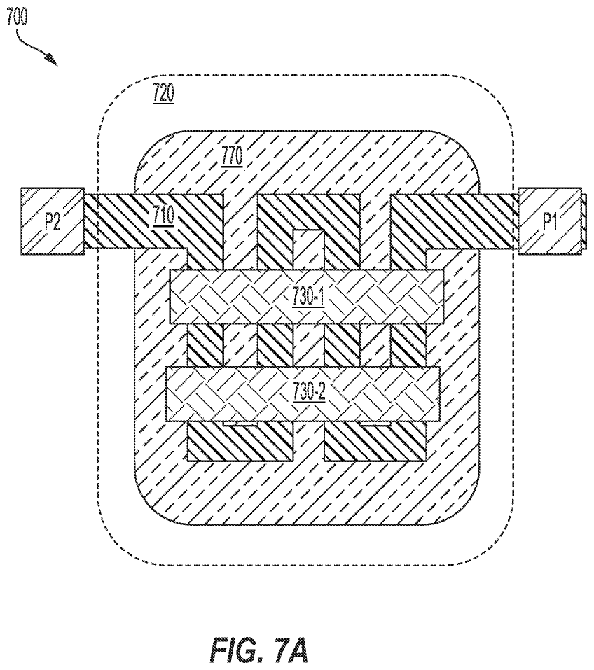

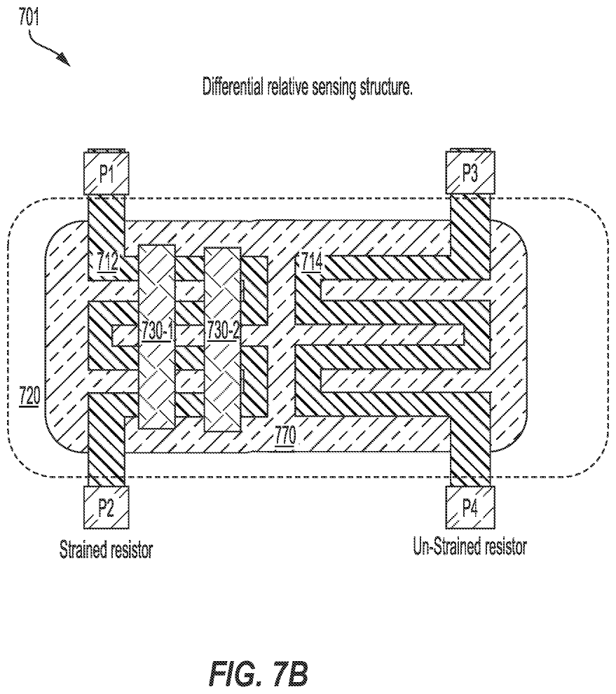

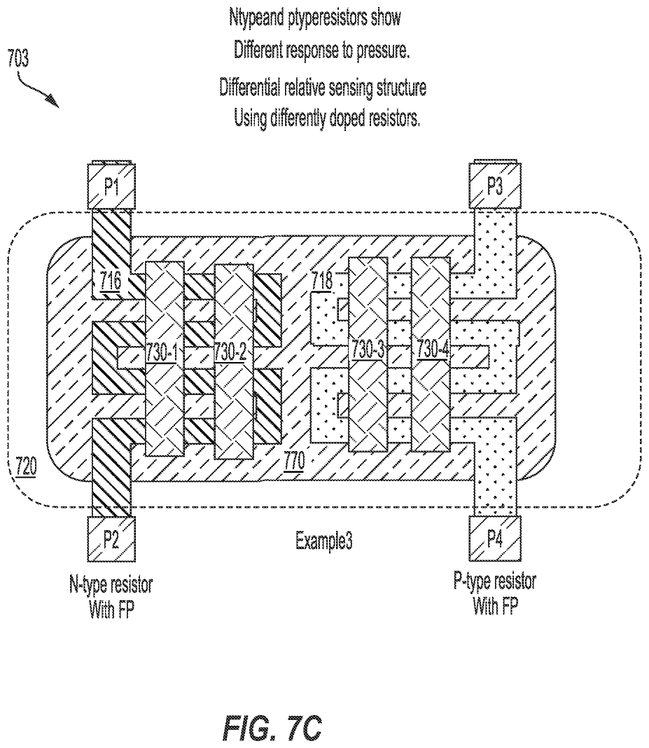

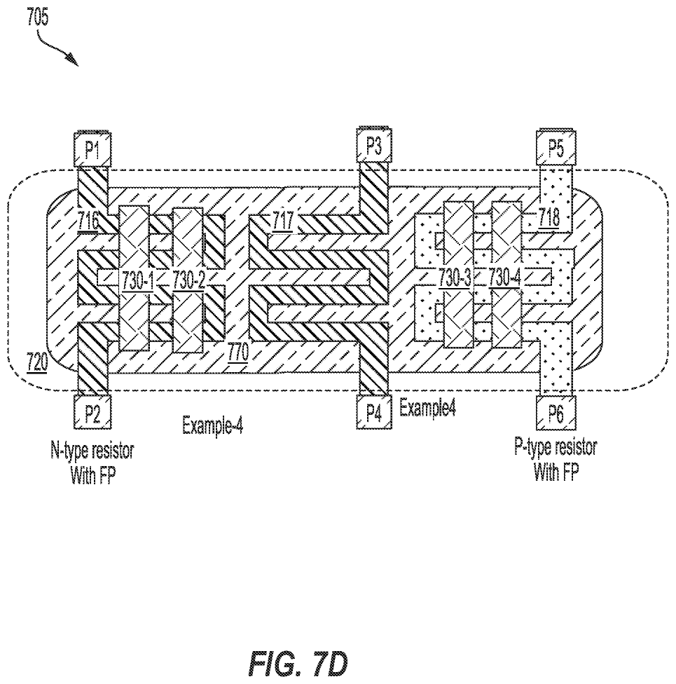

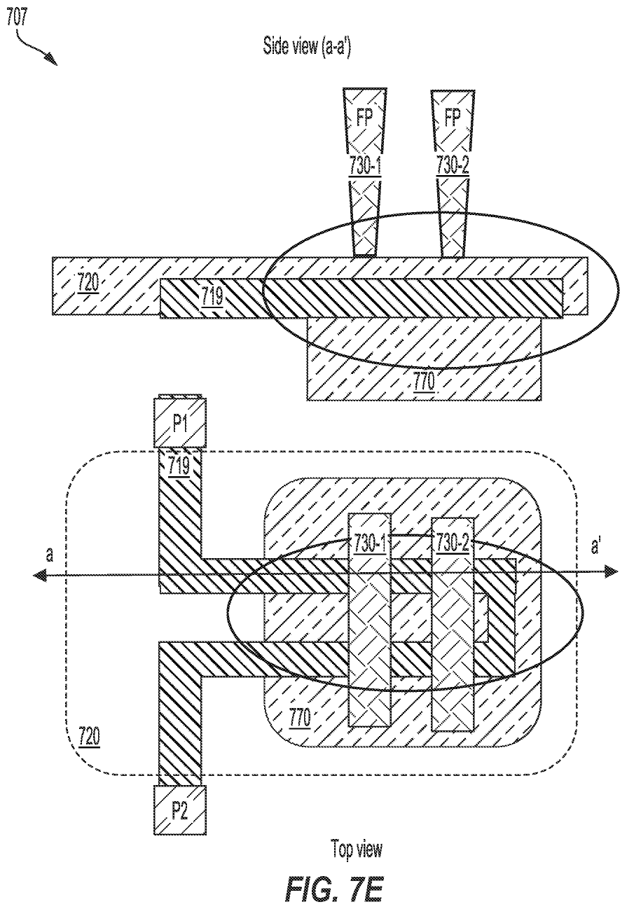

According to various aspects of the present disclosure, the external pressure plate 540 provides an example for a pressure transfer method from the external pressure plate 540 through the external pressure/strain sense bumps 560 to active/passive devices in the CMOS die 510. FIGS. 7A-7E illustrate implementation of the pressure/strain sensor using an external plate for picking up the pressure/strain and converting the pressure/strain to an electrical signal for a CMOS detection. In various aspects of the present disclosure, a resistance change (e.g., based on resistor shape change) as well as a mobility change (piezo resistance) for resistors enables CMOS detection, for example, as shown in FIG. 6A-6H.

FIGS. 6A-6H are block diagrams illustrating a pressure/strain sensing device utilizing an integrated circuit (IC) structure, according to various aspects of the present disclosure. FIGS. 6A and 6B illustrate a top view and a cross-sectional view, respectively, of an IC structure 600, along a cutline AA′. As shown in FIG. 6B, the IC structure 600 includes a substrate 602 having an active/passive device 610 in the substrate 602, including a buried layer 604 (e.g., an N-type buried layer (NBL)). In this example, the active/passive device 610 includes a first terminal 612 and a second terminal 614 and is shown as a diffusion resistor having a diffusion region 616 (N-type N+ region) on the substrate 602. In various aspects of the present disclosure, the IC structure 600 includes a set of contact field plates 630 (630-1, 630-2, 630-3), such as a first contact field plate 630-1, a second contact field plate 630-2, and a third contact field plate 630-1, between the first terminal 612 and the second terminal 614.

According to various aspects of the present disclosure, the IC structure 600 includes a dielectric layer 620 (e.g., silicon oxide (SiO₂/tetraethyl orthosilicate (TEOS))) between the set of contact field plates 630 and the diffusion region 616. Additionally, an oxide layer 622 (e.g., silicon nitride (SiN)) is deposited on the dielectric layer 620. In this example, the dielectric layer 620 enables a mechanical pressure/strain to contact directly between the diffusion region 616 and the set of contact field plates 630. Additionally, a first (M1) metal layer is coupled to the set of contact field plates 630 and provides a pressure transfer field plate 640 of the pressure/strain sensing device. In various aspects of the present disclosure, the set of contact field plates 630 is reused as an external strain-transfer mechanism without electrical connection to the active/passive device 610.

As shown in FIG. 6B, the IC structure 600 is formed on the bulk semiconductor (e.g., silicon) substrate 602 according to, for example, a bipolar junction transistor (BJT) configuration, in which N-type diffusion (N+) regions 608 are collector regions, including an adjacent shallow trench isolation (STI) layer 606. In this example, metal to diffusion (MD) contacts to the N-type diffusion regions 608 form an electrical guard-ring 642 for electrical isolation, as further illustrated in FIG. 6A. An M1 metal layer on these MD contacts completes formation of the electrical guard-ring 642. Additionally, MD contacts to the first terminal 612 and the second terminal 614 of the active/passive device 610 are also provided. The M1 metal layer on these MD contacts completes formation of a first resistor electrical contact 644 and a second resistor electrical contact 646, as further illustrated in FIG. 6A.

FIGS. 6C and 6D illustrate a top view and a cross-sectional view, respectively, of an IC structure 650, along a cutline AA′. As shown in FIG. 6D, the IC structure 650 includes a semiconductor-on-insulator (SOI) substrate 601, including a buried oxide (BOX) layer 605 on a handle wafer 603, and the active/passive device 610 on the STI layer 606 on the BOX layer 605. In this example, the active/passive device 610 is also shown as a diffusion resistor having the diffusion region 616 on the STI layer 606. Additionally, the IC structure 650 includes the set of contact field plates 630 between the first terminal 612 and the second terminal 614.

According to various aspects of the present disclosure, the IC structure 650 includes a dielectric layer 620 between the set of contact field plates 630 and the diffusion region 616, and the oxide layer 622 is on the dielectric layer 620. In this example, the dielectric layer 620 also enables a mechanical pressure/strain to contact directly between the diffusion region 616 and the set of contact field plates 630. Additionally, the pressure transfer field plate 640 of the pressure/strain sensing device in combination with the set of contact field plates 630 provides an external strain-transfer mechanism without electrical connection to the active/passive device 610.

As shown in FIG. 6D, the IC structure 650 is formed on the SOI substrate 601. In this example, MD contacts to the first terminal 612 and the second terminal 614 of the active/passive device 610 are also provided. Additionally, the M1 metal layer on these MD contacts completes formation of the first resistor electrical contact 644 and the second resistor electrical contact 646, as further illustrated in FIG. 6C. In contrast to the IC structure 600 shown in FIGS. 6A and 6B, the IC structure 650 may or may not include the electrical guard-ring 642, depending on a noise isolation specification.

FIGS. 6E and 6F illustrate a top view and a cross-sectional view, respectively, of an IC structure 660, along a cutline AA′. As shown in FIGS. 6E and 6F, the IC structure 660 is shown and described with the same reference numbers as the IC structure 650 shown in FIGS. 6C and 6D. According to various aspects of the present disclosure, the IC structure 660 is a modification of the IC structure 650 shown in FIGS. 6C and 6D for providing an air cavity 670 between the BOX layer 605 and the diffusion region 616 on the STI layer 606. In various aspects of the present disclosure, providing the air cavity 670 between the BOX layer 605 and the diffusion region 616 of the IC structure 660 enables the use of strain versus conductivity (e.g., resistivity) for measuring strain sensitivity, for example, as shown in FIG. 6G.

FIG. 6G further illustrates the IC structure 660 shown in FIGS. 6E and 6F during operation, according to various aspects of the present disclosure. In this example, the IC structure 660 is initially shown in an unstrained situation. As further illustrated in FIG. 6G, the IC structure 660 is subsequently shown in a strained situation, in which a force/pressure 680 is applied to the pressure transfer field plate 640. According to various aspects of the present disclosure, a strain versus conductivity (e.g., resistivity(R)) for measuring strain sensitivity may be performed, for example, as shown in Equation (1), in which an overall resistance change equals a piezo-resistance (p) plus a geometry based resistance (Rgeom), which is a mechanical Young's modulus (εₗ) and a Poisson ratio (v) combination.

$$\frac{Δ R}{R} = \frac{Δ ρ}{ρ} + {ε}_{l} ( 1 + 2 v ) \qquad ( 1 )$$

As shown in FIG. 6G, the diffusion region 616 of the active/passive device 610 may be implemented using polysilicon and/or a silicon (Si) doped with an N-type or P-type implant, which exhibits a favorable change in resistivity (e.g., conductivity) with an application (e.g., internal, or external) strain. In this example, Equation (1) measures a change in resistance from a strain (physical) change and a piezo-resistance (conductivity) change. As shown in Equation (1), a total resistance change=piezo resistance (mobility)+change in a shape of a resistor.

TABLE I
Film Thickness Variation to Increase/Decrease Electrical Resistance

| | | | Geometrical | |
|---|---|---|---|---|
| | | | Electrical | |
| | | Piezo Electrical | Resistance | |
| Terminal | | Resistance | Sensitivity | |
| name | Film thickness | sensitivity (Rp) | (Rgeom) | comments |
| A, C | Thin (e.g., | Higher | Higher | More sensitive |
| | ~300A) | (Rp_a, Rp_c) | (Rg_a, Rg_c) | to ambient |
| | | | | pressure |
| B, D | Thick (e.g., | Lower (Rp_b, | Lower | Less sensitive |
| | ~800A) | Rp_d) | (Rg_b, | to ambient |
| | | | Rg_d) | pressure |
| E | None | NA | NA | Electrical |
| | | | | contact |

FIG. 6H, illustrates an exploded view 690 of the IC structure 660 of FIG. 6G to further illustrate reuse of the field plate as a mechanical pressure contact for the diffusion region 616 (e.g., a diffusion resistor) for sensing mechanical pressure. In operation, sensing mechanical pressure from the diffusion region 616 is controlled by adjusting a thickness of the dielectric layer 620 as well as a contact area. The exploded view 690 illustrates a variable thickness dielectric layer 620 (e.g., 620-A, 620-B, 620-C, 620-D) each associated with a corresponding contact field plate 630 (e.g., 630-A, 630-B, 630-C, 630-D).

As shown Table I, a thickness of the dielectric 620 under the contact field plate 630 is variable, which allows for differential pressure resistance (Rpressure=Rgeom+Rpiezo). For example, as shown in Table I, dielectric portions 620-A and 620-C corresponding to CFPs 630-A and 630-C have a reduced dielectric film thickness (e.g., ˜300 A), resulting in a higher pressure sensitivity, hence more electrical resistance change (Rpressure_a, Rpressure_c). Conversely, as shown in Table I, dielectric portions 620-B and 620-D corresponding to CFPs 630-B and 630-D have an increased dielectric film thickness (e.g., ˜800 A), resulting in a decreased sensitivity to the external pressure and hence less change to the electrical resistance from external pressure (R pressure_b, R pressure_d). According to the various aspects of the present disclosure, the variable thickness dielectric layer 620 under the CFPs 630 enables uniform/gradient based pressure (e.g., diffusion pressure). Various resistor configurations for measuring resistance change are shown, for example, in FIGS. 7A-7E.

FIGS. 7A-7E are block diagrams illustrating design variations of a strain/pressure sensitive resistor, according to various aspects of the present disclosure. FIG. 7A illustrates a first strain/pressure sensitive resistor design 700, in which a resistor 710 (e.g., a polysilicon/diffusion/titanium nitride (TiN) resistor) is formed in a serpentine shape on an air cavity 770. In this example, a dielectric layer 720 is shown between the resistor 710 and a set of field plates 730 (a first field plate 730-1, and a second field plate 730-2), in which the resistor 710 includes a first terminal P1 and a second terminal P2. In other implementations, there may be more or fewer field plates than the two shown in FIG. 7A. Additionally, the set of field plates 730 is electrically insulated from the resistor 710 by the dielectric layer 720 between the set of field plates 730 and the resistor 710. The dielectric layer 720 may be composed of fluorosilicate glass (FSG) oxide, silicon nitride (SiN), titanium nitride (TiN), or other like dielectric material.

FIG. 7B illustrates a second strain/pressure sensitive resistor design 701, according to various aspects of the present disclosure. In this example, the second strain/pressure sensitive resistor design 701 is shown in a differential relative sensing structure configuration in which a strained resistor 712 is also formed in the serpentine shape on the air cavity 770. Additionally, an unstrained resistor 714 is also formed in the serpentine shape on the air cavity 770. In this example, the dielectric layer 720 is also shown between the strained resistor 712 and the set of field plates 730 (e.g., a first field plate 730-1, and a second field plate 730-2), in which the strained resistor 712 includes a first terminal P1 and a second terminal P2, and the unstrained resistor 714 includes a third terminal P3 and a fourth terminal P4. According to various aspects of the present disclosure, N-type and P-type resistors may exhibit a different response to pressure, for example, as shown in FIGS. 7C and 7D.

FIG. 7C illustrates a third strain/pressure sensitive resistor design 703, according to various aspects of the present disclosure. In this example, the third strain/pressure sensitive resistor design 703 is shown in a differential relative sensing structure configuration, using differently doped resistors. In this example, a first strained resistor 716 (e.g., N-type) is also formed in the serpentine shape on the air cavity 770. Additionally, a second strained resistor 718 (e.g., P-type) is formed in the serpentine shape on the air cavity 770. The dielectric layer 720 is also shown between the first strained resistor 716 and the first set of field plates 730 (e.g., a first field plate 730-1, and a second field plate 730-2) and between the second strained resistor 718 and a second set of field plates 730 (e.g., a third field plate 730-3, and a fourth field plate 730-4). The first strained resistor 716 includes a first terminal P1 and a second terminal P2, and the second strained resistor 718 includes a third terminal P3 and a fourth terminal P4.

FIG. 7D illustrates a fourth strain/pressure sensitive resistor design 705, according to various aspects of the present disclosure. In this example, the fourth strain/pressure sensitive resistor design 705 is shown in a differential relative sensing structure configuration, using differently doped resistors and a reference resistor. In this example, the first strained resistor 716 (e.g., N-type) is also formed in the serpentine shape on the air cavity 770. Additionally, the second strained resistor 718 (e.g., P-type) is formed in the serpentine shape on the air cavity 770. The dielectric layer 720 is also shown between the first strained resistor 716 and the first set of field plates 730 (e.g., 730-1, 730-2), and between the second strained resistor 718 and the second set of field plates 730 (e.g., 730-3, 730-4). Additionally, the first strained resistor 716 includes a first terminal P1 and a second terminal P2, and the second strained resistor 718 includes a fifth terminal P5 and a sixth terminal P6. In this example, a reference resistor 717 is between the first strained resistor 716 and the second strained resistor 718 and includes a third terminal P3 and a fourth terminal P4.

FIG. 7E illustrates a side view and a top view of a fifth strain/pressure sensitive resistor design 707 along a cutline aa′, according to various aspects of the present disclosure. In this example, the fifth strain/pressure sensitive resistor design 707 is shown in a differential relative sensing structure configuration in which an extended resistor 719 is formed in a serpentine shape on the air cavity 770. In this example, the dielectric layer 720 is also shown between the extended resistor 719 and the set of field plates 730 (e.g., 730-1, 730-2), in which the extended resistor 719 includes a first terminal P1 and a second terminal P2.

As shown in FIG. 7E, the fifth strain/pressure sensitive resistor design 707 provides an example in which an extended diffusion region of the extended resistor 719 is more flexible in the air cavity 770 to increase sensitivity to external pressure/strain. This design enhances the torsion on the resistor using the set of field plates 730 for passing the external pressure to provide improved sensitivity and behaves similar to a load mass. As shown in FIG. 7E, the mechanical bending from resistor shape changes is further augmented using the air cavity 770 under the resistors (e.g., enabling further bending) and, hence, a larger resistance change in the pressure/strain sensor device.

Beneficially, the presence of the dielectric layer 720 (e.g., ˜800-1000 Angstrom (A) thickness) provides an electrically insulated connection to the pressure/strain sensing element electrically, which avoids electrical overstimulation (EOS)/electrostatic discharge (ESD) (EOS/ESD) protection. Additionally, the sensitivity of the resistors (and other sensing elements) can be increased by fabricating the sensor on top of the air cavity 770, which supports a more efficient response to external pressure and an increased sensitivity to the applied strain. A control device, similar to the sensing element, can also be added without the external connection to use as reference for more accurate strain measurements.

FIGS. 7A-7E illustrate calculations of the sensitivity of a structure to determine how much pressure transfers to a pressure/strain sensor. According to various aspects of the present disclosure, determining how much pressure transfers to a pressure/strain sensor is useful for sensing an outside pressure, for example, as performed for altitude detection. Additionally, determining how much the pressure transfers to the pressure/strain sensor enables a shock sensor configured to detect a fall/knocking off of a device including the shock sensor, as well as a strain sensor to detect a collision (e.g., a vehicle) with a device including the strain sensor.

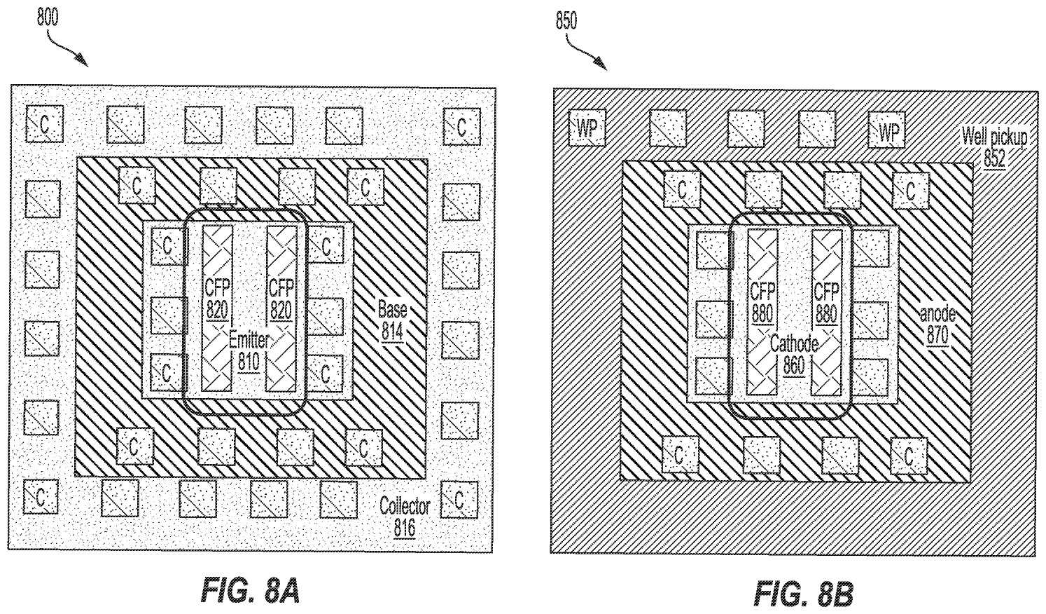

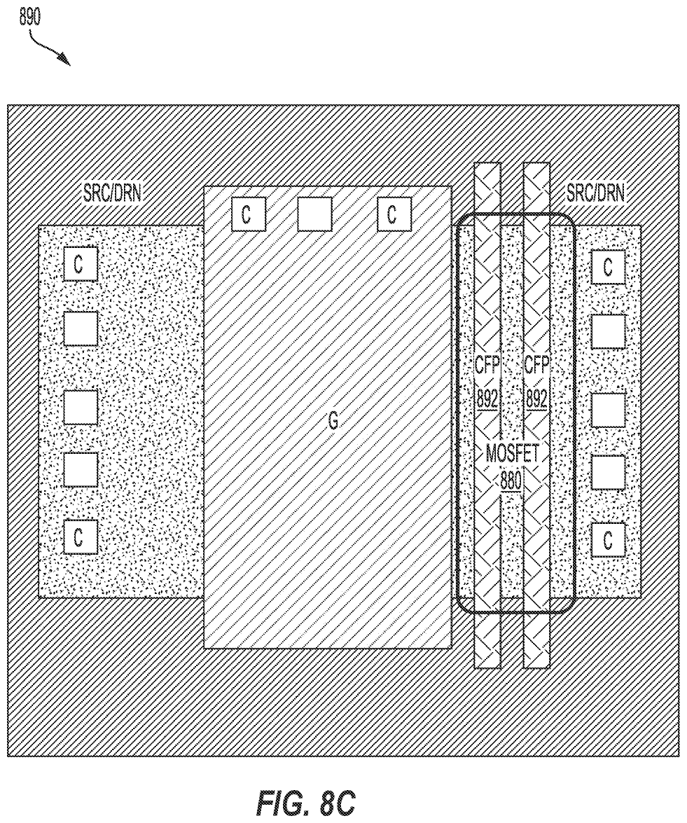

FIGS. 8A and 8B are block diagrams illustrating alternative contact field plate (CFP) implementations of a pressure/strain sensing device, according to various aspects of the present disclosure. In these aspects of the present disclosure, as shown in FIG. 8A, a pressure/strain sensing device 800 includes a CFP 820 on a terminal of an active device 810. The active device 810 is shown as an emitter of a bipolar junction transistor (BJT), including a base layer 814 and a collector layer 816. In this example, the collector layer 816 is formed from an N-type semiconductor (e.g., an N-type buried layer (NBL) of silicon (Si)). Additionally, the base layer 814 is formed in a P-type diffusion region, and the emitter (e.g., terminal) is formed in an N-type region. In this example, electrical contacts (C) are also shown. Although FIG. 8A illustrates the CFP 820 on the emitter, according to various aspects of the present disclosure, the CFP 820 may be on the emitter, the base layer 814, the collector layer 816 or multiple terminals, depending on a final application design.

As shown in FIG. 8B, a pressure/strain sensing device 850 includes a contact field plate (CFP) 880 on a terminal of an active device 860. The active device 860 is a cathode of a diode, including an anode 870 in a well region 852 (e.g., a P-type well of silicon (Si)). In this example, the anode 870 is in a P-type diffusion region (e.g., a P-type silicon (Si)). Additionally, the cathode is formed in an N-type diffusion region (e.g., an N-type silicon (Si)). In this example, the well region 852 includes well pickups (WP) and electrical contacts (C). Although FIG. 8B illustrates the CFP 880 on the cathode, according to various aspects of the present disclosure, the CFP 880 may be on the cathode, the anode 870, or multiple terminals, depending on a final application design.

As shown in FIG. 8C, a pressure/strain sensing device 890 includes a pair of contact field plates (CFPs) 892 on a terminal of an active device 860. The active device 860 is a metal-oxide-semiconductor (MOS) field effect transistor (MOSFET), including a source/drain (SRC/DRN) terminal, a drain/source (DRN/SRC) terminal, a gate (G) terminal, and electrical contacts (C). In this example, the pair of CFPs 892 are the SRC/DRN terminal. In operation, the pressure/strain sensing device 890 generates increased current in response to increased tensile stress.

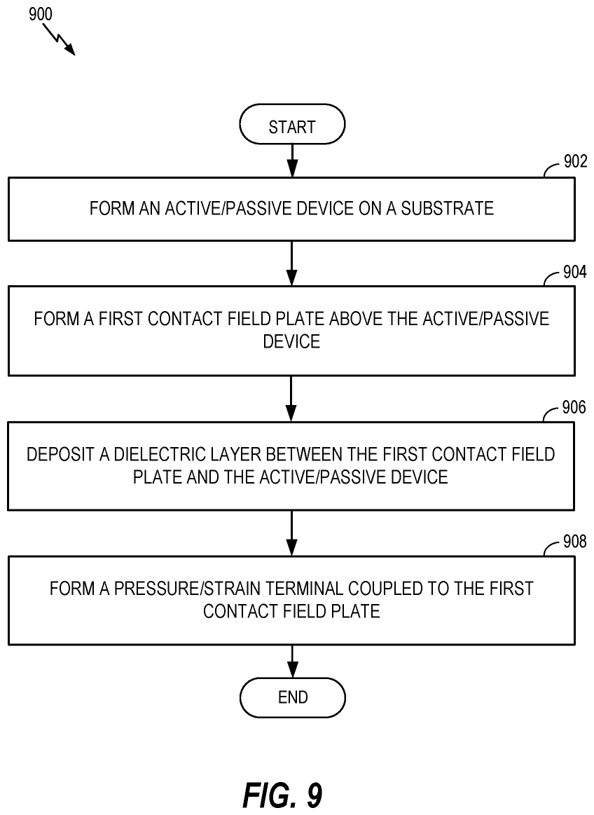

FIG. 9 is a process flow diagram illustrating a method 900 for fabricating a pressure/strain sensing device using an integrated circuit (IC) structure, according to various aspects of the present disclosure. The method 900 begins at block 902, in which an active/passive device is formed on a substrate. For example, as shown in FIG. 4A, the IC pressure/strain sensing device 400 includes a polysilicon gate (G) on the SOI layer 408. Additionally, the IC pressure/strain sensing device 400 includes a first resistor 410 on the STI layer 406, and a second resistor 420 on the SOI layer 408. As shown in FIG. 8A, a pressure/strain sensing device 800 includes a CFP 820 on a terminal of an active device 810. The active device 810 is shown as an emitter of a bipolar junction transistor (BJT), including a base layer 814 and a collector layer 816.

At block 904, a first contact field plate is formed above the active/passive device. For example, as shown in FIG. 4A, the IC pressure/strain sensing device 400 includes a first contact field plate 430 above (e.g., over) the polysilicon layer 414. As shown in FIGS. 6A-6H, the IC structure 600 includes a set of contact field plates 630 (630-1, 630-2, 630-3), such as a first contact field plate 630-1, a second contact field plate 630-2, and a third contact field plate 630-1, between the first terminal 612 and the second terminal 614.

At block 906, a dielectric layer is deposited between the first contact field plate and the active/passive device. For example, as shown in FIG. 4A, the IC pressure/strain sensing device 400 further includes a dielectric layer 412 (e.g., fluorosilicate glass (FSG) oxide, silicon nitride (SiN), or titanium nitride (TIN)) between the first contact field plate 430 and the polysilicon layer 414 to provide a mechanical pressure contact directly between the polysilicon layer 414 and the first contact field plate 430. As shown in FIGS. 6A-6H, the IC structure 600 includes the dielectric layer 620 (e.g., silicon oxide (SiO₂/tetraethyl orthosilicate (TEOS))) between the set of contact field plates 630 and the diffusion region 616.

At block 908, a pressure/strain terminal is formed and coupled to the first contact field plate. For example, as shown in FIG. 4A, the first (M1) metal layer is coupled to the first contact field plate 430 for providing a first pressure/strain terminal 432 of the IC pressure/strain sensing device 400. As shown in FIGS. 6A-6H, the first (M1) metal layer is coupled to the set of contact field plates 630 and provides a pressure transfer field plate 640 of the pressure/strain sensing device. In various aspects of the present disclosure, the set of contact field plates 630 is reused as an external strain-transfer mechanism without electrical connection to the active/passive device 610.

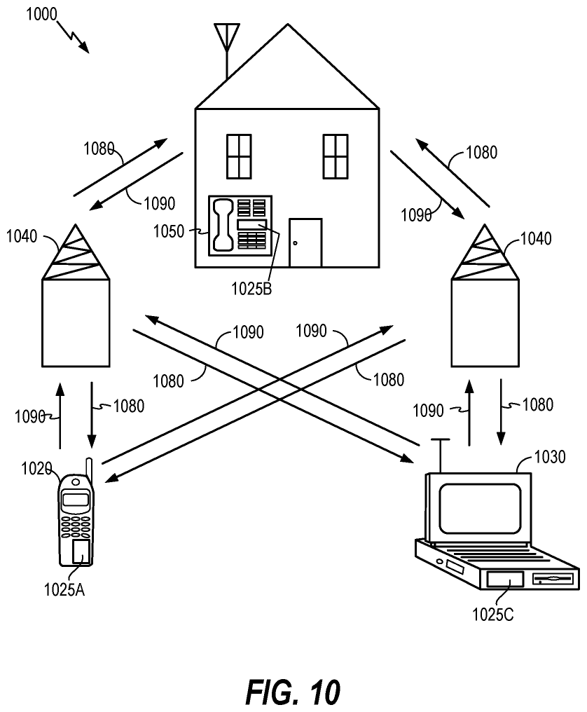

FIG. 10 is a block diagram showing an exemplary wireless communications system 1000 in which an aspect of the present disclosure may be advantageously employed. For purposes of illustration, FIG. 10 shows three remote units 1020, 1030, and 1050, and two base stations 1040. It will be recognized that wireless communications systems may have many more remote units and base stations. Remote units 1020, 1030, and 1050 include IC devices 1025A, 1025C, and 1025B that include the disclosed IC structure. It will be recognized that other devices may also include the disclosed IC structure, such as the base stations, switching devices, and network equipment. FIG. 10 shows forward link signals 1080 from the base station 1040 to the remote units 1020, 1030, and 1050, and reverse link signals 1090 from the remote units 1020, 1030, and 1050 to base station 1040.

In FIG. 10, remote unit 1020 is shown as a mobile telephone, remote unit 1030 is shown as a portable computer, and remote unit 1050 is shown as a fixed location remote unit in a wireless local loop system. For example, the remote units may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as meter reading equipment, or other devices that store or retrieve data or computer instructions, or combinations thereof. Although FIG. 10 illustrates remote units according to the aspects of the disclosure, the disclosure is not limited to these exemplary illustrated units. Aspects of the disclosure may be suitably employed in many devices, which include the disclosed IC structure.

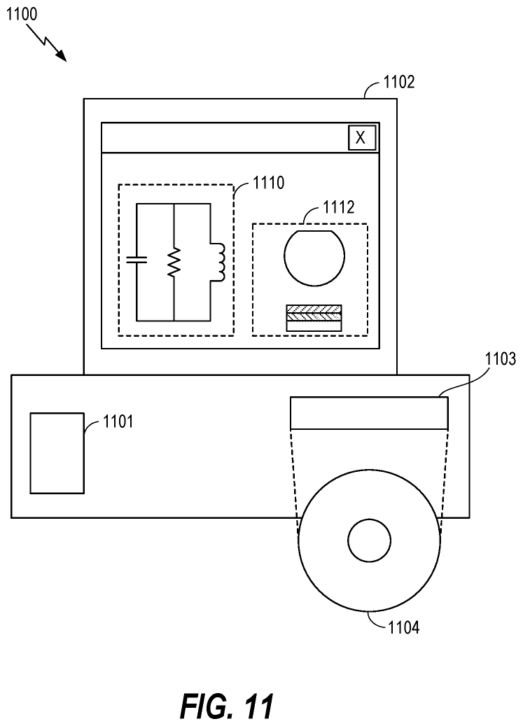

FIG. 11 is a block diagram illustrating a design workstation used for circuit, layout, and logic design of an integrated circuit (IC) structure, such as the IC structure disclosed above. A design workstation 1100 includes a hard disk 1101 containing operating system software, support files, and design software such as Cadence or OrCAD. The design workstation 1100 also includes a display 1102 to facilitate design of a circuit 1110 or an IC structure 1112 including an IC structure. A storage medium 1104 is provided for tangibly storing the design of the circuit 1110 or the IC structure 1112. The design of the circuit 1110 or the IC structure 1112 may be stored on the storage medium 1104 in a file format such as GDSII or GERBER. The storage medium 1104 may be a CD-ROM, DVD, hard disk, flash memory, or other appropriate device. Furthermore, the design workstation 1100 includes a drive apparatus 1103 for accepting input from or writing output to the storage medium 1104.

Data recorded on the storage medium 1104 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1104 facilitates the design of the circuit 1110 or the IC structure 1112 by decreasing the number of processes for designing semiconductor wafers.

Implementation examples are described in the following numbered clauses:

1. An integrated circuit (IC) structure, comprising:
a substrate;
a device on the substrate;
a first contact field plate above the device;
a dielectric layer between the first contact field plate and the device; and
a pressure/strain terminal coupled to the first contact field plate.

2. The IC structure of clause 1, in which the device comprises a bipolar junction transistor (BJT), having an emitter coupled to the first contact field plate through the dielectric layer.

3. The IC structure of clause 1, in which the device comprises a complementary metal oxide semiconductor (CMOS) diffusion resistor and/or a polysilicon resistor.

4. The IC structure of clause 1, in which the device comprises a diode, having an anode or a cathode coupled to the first contact field plate through the dielectric layer.

5. The IC structure of any of clause 1-4, in which the dielectric layer comprises fluorosilicate glass (FSG) oxide, silicon nitride (SiN), or titanium nitride (TiN).

6. The IC structure of any of clause 1-5, in which the first contact field plate comprises tungsten (W).

7. The IC structure of any of clause 1-6, in which the pressure/strain terminal comprises a first (M1) metal layer coupled to the first contact field plate.

8. The IC structure of clause 7, further comprising an external pressure/strain sense bump coupled to the pressure/strain terminal.

9. The IC structure of clause 7, further comprising:
a second contact field plate coupled to the dielectric layer;
a third contact field plate coupled to the dielectric layer; and
a pressure transfer field plate coupled to the second contact field plate and the third contact field plate.

10. The IC structure of any of clause 1-9, further comprises an air cavity between the substrate and the device.

11. A method for fabricating a pressure/strain sensing device using an integrated circuit (IC) structure, the method comprising:
forming an active/passive device on a substrate;
forming a first contact field plate above the active/passive device;
depositing a dielectric layer between the first contact field plate and the active/passive device; and
forming a pressure/strain terminal coupled to the first contact field plate.

12. The method of clause 11, in which the active/passive device comprises a bipolar junction transistor (BJT), having an emitter coupled to the first contact field plate through the dielectric layer.

13. The method of clause 11, in which the active/passive device comprises a complementary metal oxide semiconductor (CMOS) diffusion resistor and/or a polysilicon resistor.

14. The method of clause 11, in which the active/passive device comprises a diode, having an anode or a cathode coupled to the first contact field plate through the dielectric layer.

15. The method of any of clause 11-14, in which the dielectric layer comprises fluorosilicate glass (FSG) oxide, silicon nitride (SiN), or titanium nitride (TiN).

16. The method of any of clause 11-15, in which the first contact field plate comprises tungsten (W).

17. The method of any of clause 11-16, in which forming the pressure/strain terminal comprises depositing a first (M1) metal layer coupled to the first contact field plate.

18. The method of clause 17, further comprising forming an external pressure/strain sense bump coupled to the pressure/strain terminal.

19. The method of clause 17, further comprising:
forming a second contact field plate coupled to the dielectric layer;
forming a third contact field plate coupled to the dielectric layer; and
forming a pressure transfer field plate coupled to the second contact field plate and the third contact field plate.

20. The method of any of clause 11-19, further comprises forming an air cavity between the substrate and the active/passive device.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general-purpose or special-purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit (IC) structure, comprising:
a substrate;
a device on the substrate;
a first contact field plate above the device;
a dielectric layer between the first contact field plate and the device; and
a pressure/strain terminal coupled to the first contact field plate.

2. The IC structure of claim 1, in which the device comprises a bipolar junction transistor (BJT), having an emitter coupled to the first contact field plate through the dielectric layer.

3. The IC structure of claim 1, in which the device comprises a complementary metal oxide semiconductor (CMOS) diffusion resistor and/or a polysilicon resistor.

4. The IC structure of claim 1, in which the device comprises a diode, having an anode or a cathode coupled to the first contact field plate through the dielectric layer.

5. The IC structure of claim 1, in which the dielectric layer comprises fluorosilicate glass (FSG) oxide, silicon nitride (SiN), or titanium nitride (TiN).

6. The IC structure of claim 1, in which the first contact field plate comprises tungsten (W).

7. The IC structure of claim 1, in which the pressure/strain terminal comprises a first (M1) metal layer coupled to the first contact field plate.

8. The IC structure of claim 7, further comprising an external pressure/strain sense bump coupled to the pressure/strain terminal.

9. The IC structure of claim 7, further comprising:
a second contact field plate coupled to the dielectric layer;
a third contact field plate coupled to the dielectric layer; and
a pressure transfer field plate coupled to the second contact field plate and the third contact field plate.

10. The IC structure of claim 1, further comprises an air cavity between the substrate and the device.

11. A method for fabricating a pressure/strain sensing device using an integrated circuit (IC) structure, the method comprising:
forming an active/passive device on a substrate;
forming a first contact field plate above the active/passive device;
depositing a dielectric layer between the first contact field plate and the active/passive device; and
forming a pressure/strain terminal coupled to the first contact field plate.

12. The method of claim 11, in which the active/passive device comprises a bipolar junction transistor (BJT), having an emitter coupled to the first contact field plate through the dielectric layer.

13. The method of claim 11, in which the active/passive device comprises a complementary metal oxide semiconductor (CMOS) diffusion resistor and/or a polysilicon resistor.

14. The method of claim 11, in which the active/passive device comprises a diode, having an anode or a cathode coupled to the first contact field plate through the dielectric layer.

15. The method of claim 11, in which the dielectric layer comprises fluorosilicate glass (FSG) oxide, silicon nitride (SiN), or titanium nitride (TiN).

16. The method of claim 11, in which the first contact field plate comprises tungsten (W).

17. The method of claim 11, in which forming the pressure/strain terminal comprises depositing a first (M1) metal layer coupled to the first contact field plate.

18. The method of claim 17, further comprising forming an external pressure/strain sense bump coupled to the pressure/strain terminal.

19. The method of claim 17, further comprising:
forming a second contact field plate coupled to the dielectric layer;
forming a third contact field plate coupled to the dielectric layer; and
forming a pressure transfer field plate coupled to the second contact field plate and the third contact field plate.

20. The method of claim 11, further comprises forming an air cavity between the substrate and the active/passive device.
